(19) United States
(12) Patent Application Publication
(10) Pub. No.: US 2015/0296642 A1
(43) Pub. Date: Oct. 15, 2015

(54) LATCHING MODULE AND CABINET USING THE SAME

(71) Applicant: DELTA ELECTRONICS, INC., Taoyuan Hsien (TW)

(72) Inventors: Ming-Lung Li, Taoyuan Hsien (TW); Che-Wei Liao, Taoyuan Hsien (TW)

(21) Appl. No.: 14/336,608

(22) Filed: Jul. 21, 2014

(30) Foreign Application Priority Data
Apr. 10, 2014 (CN) 201410141078.5

(51) Int. Cl. H05K 5/02

(52) U.S. Cl. CPC H05K 5/0221

(57) ABSTRACT

A latching module includes a beam structure and a locking element. The beam structure is installed on a cabinet and has a first groove and a second groove. The locking element includes a backside plate, a first engaging part and a second engaging part. After a covering plate is inserted into the first groove of the beam structure, the first engaging part of the locking element is inserted into the first groove and the backside plate of the locking element is sustained against the covering plate, and then the second engaging part of the locking element is locked into the second groove of the beam structure, so that the locking element is securely locked on the beam structure and the covering plate is securely fixed on the cabinet by the locking element.

### FIELD OF THE INVENTION

The present invention relates to a latching module, and more particularly to a latching module for a cabinet.

### BACKGROUND OF THE INVENTION

A cabinet is widely used for containing electronic components therein. That is, the cabinet is an outer protective case for protecting electronic components. In case that the electronic components within the cabinet need to be maintained, it is a good way to easily open and detach the cabinet.

FIG. 1 schematically illustrates a portion of a conventional cabinet in a latched state. As shown in FIG. 1, the conventional cabinet 1 comprises a covering plate 10 for covering a main body thereof. Generally, the covering plate 10 is fixed on the main body through fastening elements 11. For example, the fastening elements 11 are screws. After the fastening elements 11 are penetrated through the covering plate 10, the fastening elements 11 are tightened into the main body. Consequently, the covering plate 10 can be tightly fixed on the main body. For maintaining the electronic components, the user may loosen the fastening elements 11 and detach the covering plate 10 from the main body. However, the method of using the fastening elements 11 to fix or detach the covering plate 10 still has some drawbacks. For example, since the covering plate 10 has openings for allowing the corresponding fastening elements 11 to go through, the structural integrity of the covering plate 10 is impaired. Moreover, since the fastening elements 11 are exposed outside the covering plate 10, the overall appearance of the cabinet 1 is not aesthetically pleasing. Moreover, an additional tool is necessary to tighten or loosen the fastening elements 11. In other words, the method of using the fastening elements 11 to fix or detach the covering plate 10 is time-consuming and labor-intensive. In other words, the uses of the fastening elements 11 to fix or detach the covering plate 10 have many drawbacks.

From the above discussions, fastening elements can be used to securely lock the covering plate on the main body. However, for improving the appearance of the cabinet, it is necessary to reduce the destruction of the structural integrity and enhance the aesthetically-pleasing appearance.

Therefore, there is a need of providing an improved latching module and cabinet using the latching module in order to avoid the above drawbacks.

### SUMMARY OF THE INVENTION

An object of present invention provides a latching module and a cabinet using the latching module. In accordance with the present invention, the latching module is capable of easily fixing or detaching the covering plate. Moreover, the structural integrity of the covering plate can be maintained and the aesthetically-pleasing appearance of the cabinet can be enhanced. Moreover, the method of using the latching module to install the covering plate is more time-saving and labor-saving. Moreover, since the locking element of the latching module is easily detached, the electronic components within the cabinet can be maintained more easily.

In accordance with an aspect of the present invention, there is provided a latching module for a covering plate of a cabinet. The latching module includes a beam structure and a locking element. The beam structure is installed on the cabinet and has a first groove and a second groove. The locking element includes a backside plate, a first engaging part and a second engaging part. After the covering plate is inserted into the first groove of the beam structure, the first engaging part of the locking element is inserted into the first groove and the backside plate of the locking element is sustained against the covering plate, and then the second engaging part of the locking element is locked into the second groove of the beam structure, so that the locking element is securely locked on the beam structure and the covering plate is securely fixed on the cabinet by the locking element.

In accordance with another aspect of the present invention, there is provided a cabinet including a main body, a covering plate and a latching module. The latching module includes a beam structure and a locking element. The beam structure is installed on the main body and has a first groove and a second groove. The locking element includes a backside plate, a first engaging part and a second engaging part. After the covering plate is inserted into the first groove of the beam structure, the first engaging part of the locking element is inserted into the first groove and the backside plate of the locking element is sustained against the covering plate, and then the second engaging part of the locking element is locked into the second groove of the beam structure, so that the locking element is securely locked on the beam structure and the covering plate is securely fixed on the main body of the cabinet by the locking element.

The above contents of the present invention will become more readily apparent to those ordinarily skilled in the art after reviewing the following detailed description and accompanying drawings, in which:

### BRIEF DESCRIPTION OF THE DRAWINGS

FIG. 1 schematically illustrates a portion of a conventional cabinet in a latched state;

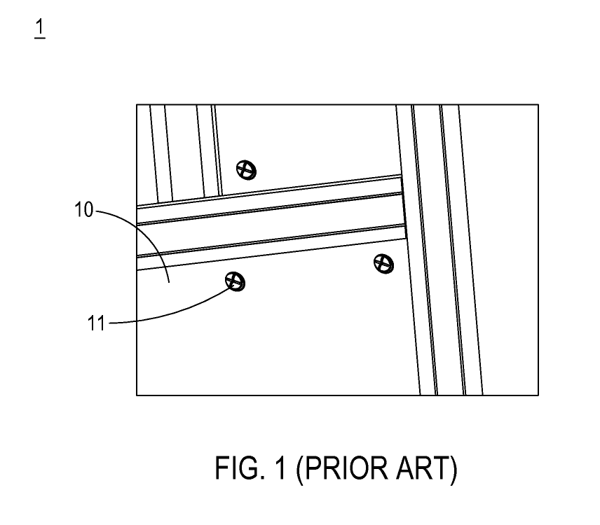

FIG. 2 schematically illustrates a portion of a cabinet according to an embodiment of the present invention;

FIG. 3A is a schematic cross-sectional view illustrating the beam structure of the latching module of FIG. 2;

FIG. 3B schematically illustrates a portion of the beam structure of the latching module of FIG. 2;

FIG. 4A is a schematic perspective view illustrating the locking element of the latching module of FIG. 2;

FIG. 4B is a schematic perspective view illustrating the locking element of the latching module of FIG. 4A and taken along another viewpoint;

FIG. 5 schematically illustrates a process of assembling the locking element and the beam structure of the latching module of FIG. 2; and

FIG. 6 is a schematic cross-sectional view illustrating the combination between the latching module and the covering plate as shown in FIG. 2.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

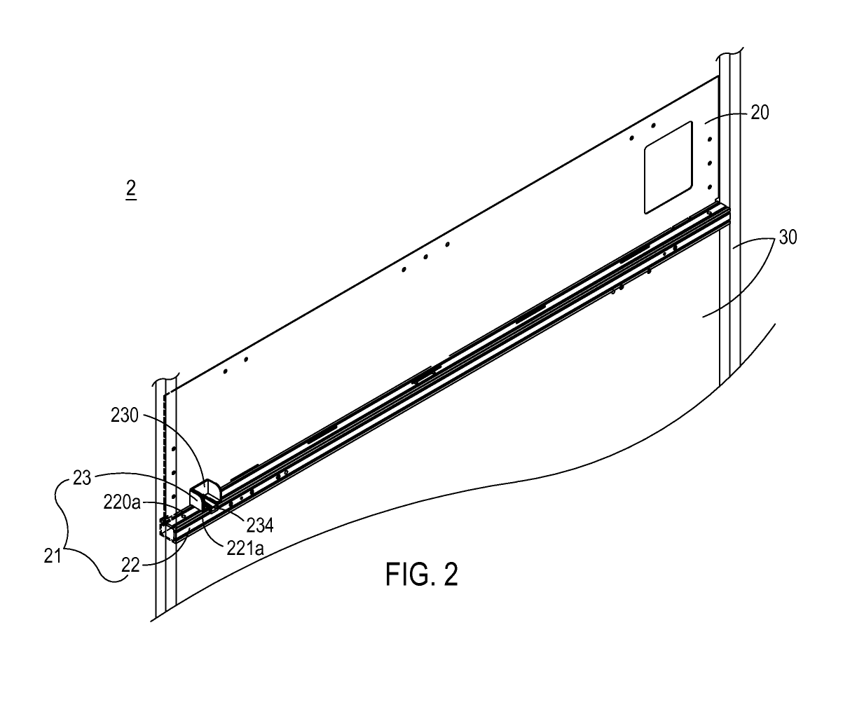

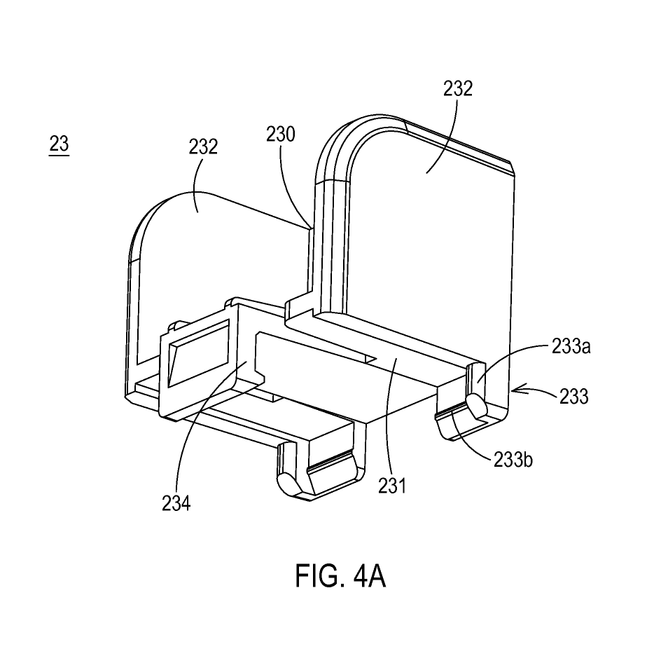

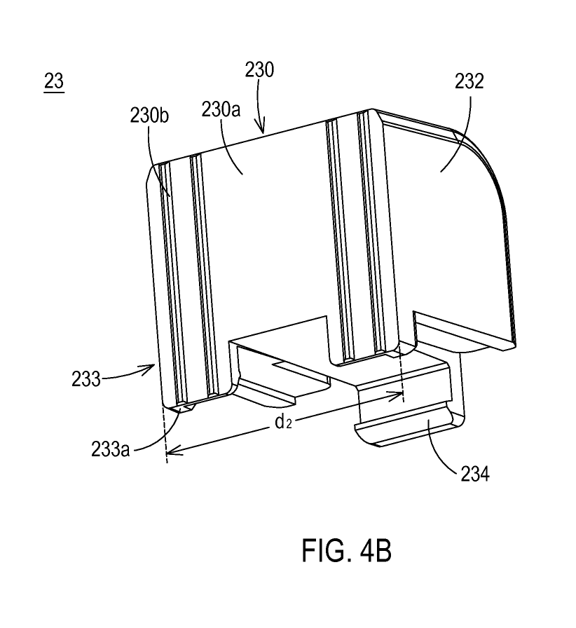

FIG. 2 schematically illustrates a portion of a cabinet according to an embodiment of the present invention. As shown in FIG. 2, the cabinet 2 at least comprises a main body 30, a covering plate 20 and a latching module 21. Through the latching module 21, the covering plate 20 is detachably fixed on the main body 30. In this embodiment, the latching module 21 comprises a beam structure 22 and a locking element 23. The beam structure 22 is installed on the main body 30 of the cabinet 2. The beam structure 22 comprises a first groove 220a and a second groove 221a. The locking element 23 comprises a backside plate 230, at least one first engaging part 233 (see FIG. 4A), and at least one second engaging part 234.

A process of assembling the covering plate 20 with the latching module 21 will be illustrated as follows. Firstly, one side of the covering plate 20 is inserted into the first groove 220a of the beam structure 22 of the latching module 21. Then, the first engaging part 233 of the locking element 23 is inserted into the first groove 220a of the beam structure 22, so that the backside plate 230 of the locking element 23 is sustained against the covering plate 20. Then, the second engaging part 234 of the locking element 23 is locked into the second groove 221a of the beam structure 22. Consequently, the locking element 23 is securely locked on the beam structure 22. Moreover, since the locking element 23 is sustained against the covering plate 20, the covering plate 20 is securely fixed on the latching module 21.

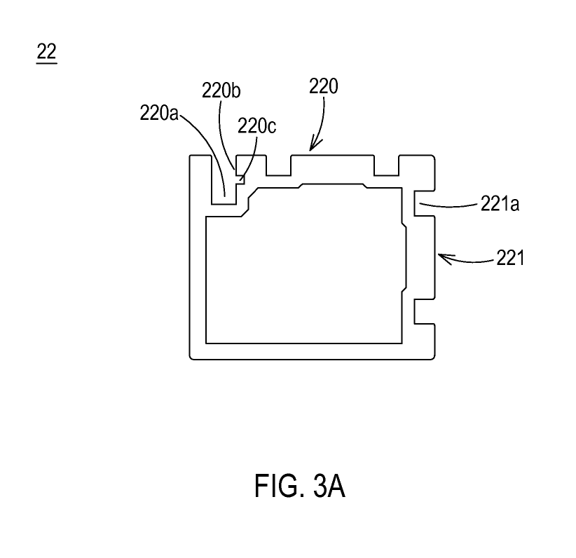

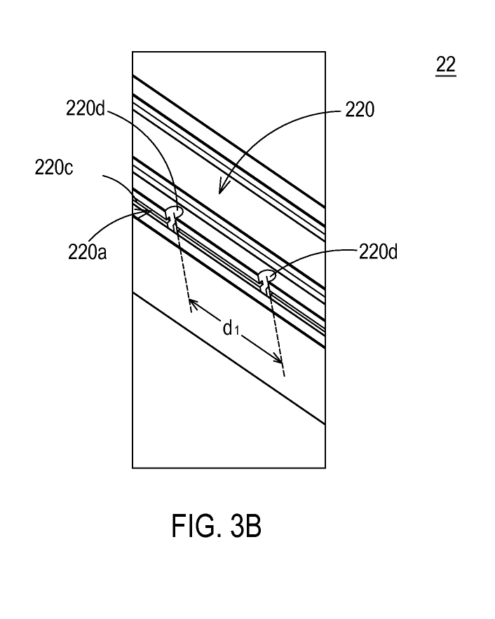

FIG. 3A is a schematic cross-sectional view illustrating the beam structure of the latching module of FIG. 2. As shown in FIG. 3A, the beam structure 22 is an elongated hollow bar, but is not limited thereto. The beam structure 22 comprises a first surface 220 and a second surface 221. The first surface 220 and the second surface 221 are located beside and perpendicular to each other. The first groove 220a is formed in the first surface 220. The second groove 221a is formed in the second surface 221. The first groove 220a of the beam structure 22 has a sidewall 220b. The sidewall 220b of the first groove 220a is in parallel with the second surface 221. Moreover, a guide recess 220c is formed in the sidewall 220b. Moreover, the locking element 23 has a positioning rib 233b (see FIG. 4A) corresponding to the guide recess 220c. When the first engaging part 233 of the locking element 23 is inserted into the first groove 220a, the positioning rib 233b is engaged with the guide recess 220c. Due to the engagement between the positioning rib 233b and the guide recess 220c, the first engaging part 233 of the locking element 23 is securely fixed in the first groove 220a.

FIG. 3B schematically illustrates a portion of the beam structure of the latching module of FIG. 2. As shown in FIG. 3B, the beam structure 22 further comprises at least one positioning hole 220d corresponding to at least one positioning leg 233a of the locking element 23 (see FIG. 4A). The at least one positioning hole 220d is formed in the first surface 220 of the beam structure 22 and located beside the first groove 220a. In this embodiment, two positioning holes 220d are formed in the first surface 220 of the beam structure 22. The distance d1 between the two positioning holes 220d is substantially identical to the distance d2 between the two positioning legs 233a of the locking element 23 (see FIG. 4B). For assembling the locking element 23 with the beam structure 22, the positioning legs 233a of the locking element 23 are aligned with the corresponding positioning holes 220d of the beam structure 22, and then the locking element 23 is intuitively and quickly locked on the beam structure 22.

It is noted that the number of the positioning holes 220d and the positions of the positioning holes 220d may be varied according to the practical requirements. Moreover, the number and the positions of the positioning holes 220d of the beam structure 22 may be determined according to the number and positions of the locking element 23.

FIG. 4A is a schematic perspective view illustrating the locking element of the latching module of FIG. 2. For example, the locking element 23 is a three-dimensional engaging seat, but is not limited thereto. In this embodiment, the locking element 23 comprises the backside plate 230, a bottom plate 231, two lateral plates 232, at least one first engaging part 233, and at least one second engaging part 234. The two lateral plates 232 are located beside and perpendicular to the backside plate 230 and the bottom plate 231. The backside plate 230 is located beside and perpendicular to the bottom plate 231. That is, the top side and the front side of the locking element 23 are vacant. The two lateral plates 232 are used for increasing the structural strength of the locking element 23 and facilitating grasping the locking element 23. It is noted that the structure of the locking element 23 may be altered according to the practical requirements. For example, in some other embodiments, the locking element 23 only comprises the backside plate 230 and the bottom plate 231.

Please refer to FIGS. 3A, 3B and 4A again. In this embodiment, the locking element 23 comprises two first engaging parts 233 and one second engaging part 234. The two first engaging parts 233 are located at two opposite edges of the backside plate 230. Moreover, the two first engaging parts 233 are protruded downwardly from the junctions between the backside plate 230 and the bottom plate 231. The second engaging part 234 is opposed to the first engaging parts 233 with respect to the bottom plate 231. In addition, the second engaging part 234 is protruded downwardly from the bottom plate 231. It is noted that the number and positions of the first engaging parts 233 may be varied according to the practical requirements. In some embodiments, the backside plate 230, the bottom plate 231, the two lateral plates 232, the first engaging parts 233 and the second engaging part 234 of the locking element 23 are integrally formed with each other. In this embodiment, each of the first engaging parts 233 comprises a positioning leg 233a and a positioning rib 233b. The positioning leg 233a is inserted into the corresponding positioning hole 220d of the beam structure 22. When the first engaging part 233 of the locking element 23 is inserted into the first groove 220a of the beam structure 22, the positioning rib 233b is engaged with the guide recess 220c. Due to the engagement between the positioning rib 233b and the guide recess 220c, the locking element 23 is quickly positioned in the first groove 220a and securely fixed in the first groove 220a.

The second engaging part 234 is opposed to the first engaging parts 233 with respect to the bottom plate 231. In this embodiment, the second engaging part 234 is a hook, and the second engaging part 234 is slightly resilient. The second engaging part 234 is locked into the second groove 221a of the beam structure 22. It is noted that the structure of the second engaging part 234 may be varied according to the practical requirements.

FIG. 4B is a schematic perspective view illustrating the locking element of the latching module of FIG. 4A and taken along another viewpoint. The backside plate 230 has a rear surface 230a. At least one raised block 230b is protruded from the rear surface 230a of the backside plate 230. Since the at least one raised block 230b is sustained against the covering plate 20, the covering plate 20 and the locking element 23 are interference-fitted into the first groove 220a through the raised block 230b. The two first engaging parts 233 are protruded downwardly from two opposite edges of the backside plate 230. Moreover, the positioning legs 233a of the two first engaging parts 233 are separated from each other by the distance d2. The distance d2 is equal to the distance d1 between the two positioning holes 220d of the beam structure 22 (see FIG. 3B). For assembling the locking element 23 with the beam structure 22, the positioning legs 233a of the locking element 23 are aligned with the corresponding positioning holes 220d of the beam structure 22, and then the locking element 23 is intuitively and quickly locked on the beam structure 22.

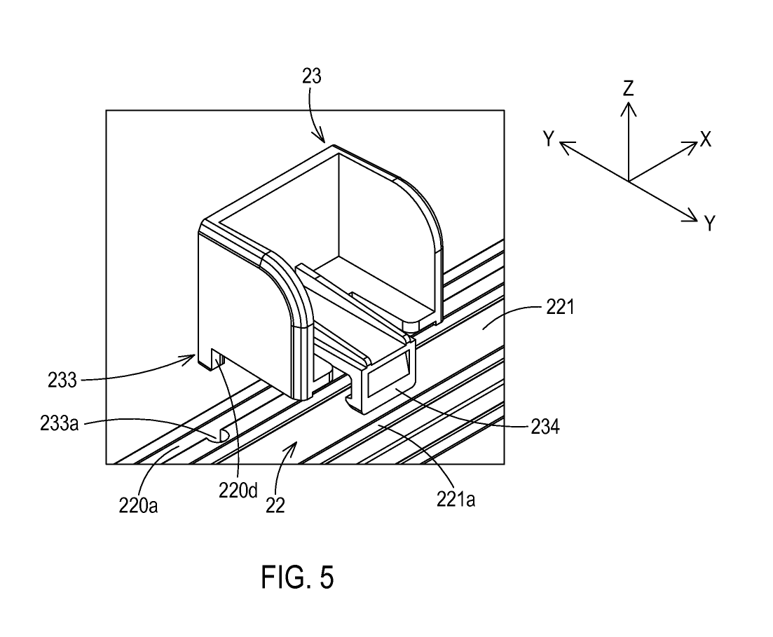

FIG. 5 schematically illustrates a process of assembling the locking element and the beam structure of the latching module of FIG. 2. For assembling the locking element 23 with the beam structure 22, the first engaging parts 233 of the locking element 23 are inserted into the first groove 220a of the beam structure 22 while the positioning legs 233a of the locking element 23 are aligned with the corresponding positioning holes 220d of the beam structure 22. Since the positioning legs 233a are inserted into the corresponding positioning holes 220d, the locking element 23 is positioned and fixed on the beam structure 22 along the X-axis direction. Next, the second engaging part 234 of the locking element 23 is locked into the second groove 221a of the beam structure 22. Consequently, the locking element 23 can be securely fixed on the beam structure 22.

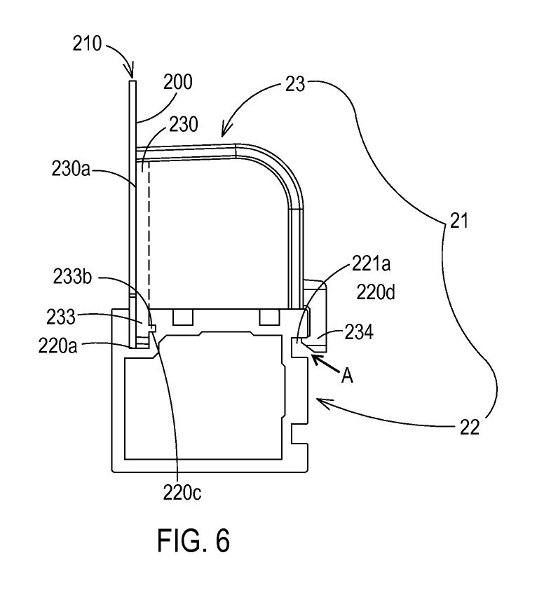

FIG. 6 is a schematic cross-sectional view illustrating the combination between the latching module and the covering plate as shown in FIG. 2. In the latching module 21, the locking element 23 is locked on the beam structure 22 through the first engaging parts 233 and the second engaging part 234. By the latching module 21, the covering plate 20 can be securely fixed on the beam structure 22. After the covering plate 20 is inserted into the first groove 220a of the beam structure 22, the positioning legs 233a of the locking element 23 are positioned in the corresponding positioning holes 220d of the beam structure 22, then the first engaging parts 233 of the locking element 23 are inserted into the first groove 220a of the beam structure 22, and finally the second engaging part 234 of the locking element 23 is locked into the second groove 221a of the beam structure 22. As shown in FIG. 6, when the first engaging parts 233 of the locking element 23 are inserted into the first groove 220a, the positioning ribs 233b of the first engaging parts 233 are engaged with the guide recesses 220c. Since the width of the first groove 220a is equal to the total width of the covering plate 20 and the first engaging part 233 of the locking element 23, the covering plate 20 and the locking element 23 are interference-fitted into the first groove 220a. Due to the engagement between the positioning ribs 233b and the guide recesses 220c and the engagement between the second engaging part 234 and the second groove 221a, the locking element 23 is securely locked on the beam structure 22 along the Y-axis direction. Moreover, due to the engagement between the first engaging parts 233 and the first groove 220a and the engagement between the positioning ribs 233b and the guide recesses 220c, the locking element 23 is securely locked on the beam structure 22 along the Z-axis direction.

Moreover, when the rear surface 230a of the backside plate 230 of the locking element 23 is sustained against a surface 200 of the covering plate 20, the covering plate 20 and the locking element 23 are interference-fitted into the first groove 220a through the at least one raised block 230b. Consequently, the covering plate 20 is securely fixed and cannot be slid. Since the locking element 23 is sustained against the covering plate 20, the locking element 23 and the covering plate 20 are securely fixed on the beam structure 22 along the Y-axis direction. From the above descriptions, the locking element 23 is securely locked on the beam structure 22 along the X-axis, Y-axis and Z-axis directions. Consequently, the covering plate 20 can be securely fixed by the latching module 21.

For detaching the locking element 23, a detaching tool (e.g. a flat-blade screwdriver) may be inserted into a space between the second engaging part 234 of the locking element 23 and the second groove 221a of the beam structure 22 along the direction A as shown in FIG. 6. After the detaching tool is inserted into a space between the second engaging part 234 of the locking element 23 and the second groove 221a of the beam structure 22, the locking element 23 can be easily disengaged from the beam structure 22. In such way, the locking element 23 and the covering plate 20 are easily detached from the beam structure 22 without hurting the surface treatment of the beam structure 22.

From the above descriptions, the present invention provides a latching module and a cabinet using the latching module. The latching module comprises a beam structure and a locking element. The beam structure comprises a first groove and a second groove. The locking element comprises a first engaging part and a second engaging part. Since the locking element is intuitively and quickly locked on the beam structure, the covering plate can be easily fixed on the main body. As previously described in the prior art, the method of using the fastening elements to fix or detach the covering plate is time-consuming and labor-intensive, the overall appearance of the cabinet is not aesthetically pleasing, and the structural integrity of the covering plate is impaired. In accordance with the present invention, the latching module is capable of easily fixing or detaching the covering plate. Moreover, after the covering plate is detached from the cabinet by detaching the locking element, the structural integrity of the covering plate can be maintained. Moreover, the method of using the latching module to install the covering plate is more time-saving and labor-saving. Moreover, since the locking element of the latching module can be easily detached, the electronic components within the cabinet can be maintained more easily.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A latching module for a covering plate of a cabinet, the latching module comprising:
a beam structure installed on the cabinet and having a first groove and a second groove; and
a locking element comprising a backside plate, a first engaging part and a second engaging part,
wherein after the covering plate is inserted into the first groove of the beam structure, the first engaging part of the locking element is inserted into the first groove and the backside plate of the locking element is sustained against the covering plate, and then the second engaging part of the locking element is locked into the second groove of the beam structure, so that the locking element is securely locked on the beam structure and the covering plate is securely fixed on the cabinet by the locking element.

2. The latching module according to claim 1, wherein a guide recess is formed in a sidewall of the first groove of the beam structure, and the first engaging part of the locking element has a positioning rib corresponding to the guide recess, wherein when the first engaging part of the locking element is inserted into the first groove, the positioning rib is engaged with the guide recess.

3. The latching module according to claim 1, wherein the beam structure is installed on a main body of the cabinet and comprises a first surface and a second surface, wherein the first surface and the second surface are located beside and perpendicular to each other, the first groove is formed in the first surface, and the second groove is formed in the second surface.

4. The latching module according to claim 3, wherein the beam structure further comprises at least one positioning hole, and the at least one positioning hole is formed in the first surface of the beam structure and located beside the first groove, wherein the first engaging part of the locking element further comprises at least one positioning leg corresponding to the at least one positioning hole, wherein when the first engaging part of the locking element is inserted into the first groove, the at least one positioning leg is positioned in the at least one positioning hole.

5. The latching module according to claim 1, wherein the backside plate has a rear surface, and at least one raised block is protruded from the rear surface of the backside plate, wherein when the locking element is sustained against the covering plate, the covering plate and the locking element are interference-fitted into the first groove through the at least one raised block.

6. The latching module according to claim 1, wherein the locking element further comprises a bottom plate, wherein the bottom plate is located beside and perpendicular to the backside plate, the first engaging part is protruded downwardly from a junction between the backside plate and the bottom plate, and the second engaging part is protruded downwardly from the bottom plate and opposed to the first engaging part with respect to the bottom plate.

7. The latching module according to claim 6, wherein the locking element further comprises two lateral plates, wherein the two lateral plates are located beside and perpendicular to the backside plate and the bottom plate.

8. The latching module according to claim 7, wherein the backside plate, the bottom plate, the two lateral plates, the first engaging parts and the second engaging part of the locking element are integrally formed with each other.

9. The latching module according to claim 1, wherein the second engaging part is a hook to be locked into the second groove of the beam structure.

10. A cabinet, comprising:
a main body;
a covering plate; and
a latching module comprising:
a beam structure installed on the main body and having a first groove and a second groove; and
a locking element comprising a backside plate, a first engaging part and a second engaging part,
wherein after the covering plate is inserted into the first groove of the beam structure, the first engaging part of the locking element is inserted into the first groove and the backside plate of the locking element is sustained against the covering plate, and then the second engaging part of the locking element is locked into the second groove of the beam structure, so that the locking element is securely locked on the beam structure and the covering plate is securely fixed on the main body of the cabinet by the locking element.
